(19) United States
(12) Patent Application Publication
(10) Pub. No.: US 2005/0151136 A1
(43) Pub. Date: Jul. 14, 2005

(54) Light emitting diode having conductive substrate and transparent emitting surface

(76) Inventor: Heng Liu, Sunnyvale, CA (US)

Correspondence Address: MACPHERSON KWOK CHEN & HEID LLP, 1762 TECHNOLOGY DRIVE, SUITE 226, SAN JOSE, CA, 95110, US

(21) Appl. No.: 10/754,366

(22) Filed: Jan. 8, 2004

(51) Int. Cl. H01L 21/00; H01L 27/15; H01L 29/26; H01L 31/12; H01L 33/00; H01L 23/34

(52) U.S. Cl. 257/79; 438/22; 438/24; 438/122; 257/712

(57) ABSTRACT

A method for forming an LED includes bonding a heat generating region of a light emitting device to a heat conductive substrate, so as to define a composite structure and so as to substantially enhance the heat dissipation. Enhancing heat dissipation from the device facilitates operation at higher currents, so as to provide greater light output therefrom.

### FIELD OF THE INVENTION

The present invention relates generally to semiconductor fabrication techniques. The present invention relates more particularly to a method for forming an LED which includes bonding a heat generating region of a light emitting device to a heat conductive substrate, so as to substantially enhance heat dissipation therefrom and thus facilitate operation of the device at higher currents in order to provide greater light output therefrom.

### BACKGROUND OF THE INVENTION

Light emitting diodes (LEDs) for use as indicators are well known. Visible light emitting LEDs have been used extensively for this purpose in consumer electronics. For example, red LEDs are commonly used to indicate that power has been applied to such devices as radios, televisions, video recorders (VCRs) and the like.

AlInGaN based LEDs have attracted much attention in recent years due to their excellent potential for use as solid state light sources, wherein they may replace many forms of traditional lighting. Thus, although in the past visible light LEDs were normally used as indicators rather than as light sources, due to the low efficiency and high cost of such contemporary LEDs, the use of AlInGaN based fabrication techniques desirably facilitates the use of LEDs for general illumination.

The current trend of the market requires that LEDs provide ever increasing intensity, so as to facilitate use in diverse lighting applications. This requirement tends to force such devices to operate at higher current densities than were traditionally required when LEDs were merely used as indicator devices. As those skilled in the art will appreciate, indicator devices typically have a very low intensity and consequently require very little current.

Several problems need to be considered when operating an LED at a higher current density. These problems include an undesirable current crowding effect, and an undesirable thermal effect (heat dissipation). Current crowding causes local heating in a device and reduces light output as well as device reliability. Even without current crowding, heat generated in the active region of the device still needs to be dissipated as fast as possible to avoid excessive temperature rise that leads to light output degradation and poor reliability.

AlInGaN based material has poor carrier mobility that results in poor conductivity. In a typical light emitting diode, injected current needs to spread out before pass through the device junction for optimum light output. Because of the poor conductivity of AlInGaN material, good current spreading is difficult to achieve with AlInGaN layers. According to one contemporary attempt to alleviate current crowding in AlInGaN based LED, a semi-transparent conductive layer (TCL) is used to distribute current evenly throughout the device. Since the TCL is made very thin to avoid light absorption, it is only effective to normal current injection (20 mA) and small device size (350×350 micron). At much higher current injection, hundreds of mA, current crowding will still occur.

A fundamental issue with any contemporary LEDs is that their efficiency can be adversely affected by heat generated within the device itself. This undesirable effect inherently limits how much electrical power is actually used to drive an LED, and thus undesirably results in a limitation on the maximum output optical power from an LED, since the amount of light that can be generated is roughly proportional to the input electrical power.

Thus, the fundamental cause of lower efficiency associated with heat is due to a temperature rise in the LED die. Higher operating temperatures not only degrade the light output efficiency, but also adversely affect the life of the LED.

Since heat generation in an LED is inherent, scientists have been trying to reduce the temperature rise by improving the heat removal rate. This can be done by placing a heat sink close to the active region of the device and by choosing a high thermal conductivity material for the heat sink.

One approach, disclosed in U.S. patent publication US2001/0032985A1, includes flipping the chip upside down, and utilizing solder bumps for the connection of chip electrodes onto an electrically patterned and thermally conductive submount. Heat generated by the light emitting device is transferred directly through the connecting solder pumps to the submount rather than through the substrate if it is not flipped. However, the heat conduction area directly in contact with the heat generating area is only about 25%, heat removal is not 100% optimized. Nonetheless, flipping the chip with the transparent substrate facing upward, and with a mirror coating on the epitaxial side enhances the light extraction. Since the index of refraction for sapphire (n=1.7) is lower than AlInGaN (n=2.5), sapphire provides a good index matching between the AlInGaN LED and the media (n=1.5 for most epoxy). The mirror coating on the epitaxial side reflects light toward the substrate. This design provides a better pathway for light to escape from the device.

In the actual practice, light efficiency is twice that of the non-flipped LED. However, the cost to make this device is high since not only a submount is required between the chip and the final package, but also a precise alignment is needed to ensure proper contact between the chip contact pads and the submount. To date, there doesn't appear to be any evidence that this process can provide acceptable yield.

Another approach is to transfer the light emitting region from a temporary substrate to a permanent conductive substrate, and remove the temporary substrate by laser ablation, such as via the laser lift off (LLO) process. The device processed by this method is a vertical device with their connecting electrodes on opposite sides of the active region. By directly bonding the heat generating region to a thermally and electrically conductive submount provides a very good path for heat removal. However, by removing the original transparent substrate to gain access for an electrical contact detriments the benefit of the effect of index matching provided by the sapphire substrate. This process is disclosed in the paper entitled “Fabrication of Thin Film InGaN Light Emitting Diode Membranes by Laser Lift Off” in Applied Physics Letters, Volume 75, No. 10.

Although such methods have proven generally suitable for their intended purposes, they possess inherent deficiencies which detract from their overall effectiveness and desirability.

As such, although the prior art has recognized, to a limited extent, the problems associated with high current operation of LEDs, the proposed solutions have, to date, been ineffective in providing a satisfactory remedy. Therefore, it is desirable to provide an LED for which the above described problems associated with high current operation are substantially mitigated.

More particularly, it is desirable to provide an LED having a desirably high rate of direct heat removal from the LED active region, such as through the use of a higher thermal conductivity substrate on the backside thereof, which results in better LED reliability and higher current density operation; which provides enhanced electrostatic discharge (ESD) performance; which provides enhanced light output efficiency due to the inverted LED structure having a thicker transparent substrate on top of the emitting region without any metallization to block light emission and having an internal reflector to avoid absorption of the substrate material so as to allow more light escape from the chip due to a reduction of internal reflection.

### BRIEF SUMMARY OF THE INVENTION

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112.

The present invention specifically addresses and alleviates the above mentioned deficiencies associated with the prior art. More particularly, according to one aspect, the present invention comprises a method for forming an LED, wherein the method comprises bonding a heat generating region of a light emitting device to a heat conductive substrate so as to define a composite structure which substantially enhances heat dissipation from the light emitting device. Preferably, bonding a heat generating region of a light emitting device to a heat conductive substrate comprises directly bonding the heat generating region of the light emitting device to the heat conductive substrate.

Preferably, bonding the heat generating region of a light emitting device to a heat conductive substrate comprises directly bonding a heat generating region comprising a transparent substrate, a first semiconductor layer, a second semiconductor layer, an active layer defined between the first and second semiconductor layers, a reflector, and metal bonding layer to the heat conductive substrate.

Preferably, bonding the heat generating region of a light emitting device to a heat conductive substrate comprises directly bonding the heat generating region to a heat conductive substrate comprising a silicon layer and a metal bonding layer.

Preferably, the heat generating region of the light emitting device comprises a metal bonding layer and the heat conductive substrate comprises a metal bonding layer. Thus, the two metal bonding layers are attached to one another.

The method preferably further comprises cleaning both metal bonding layers prior to bonding the heat generating region of a light emitting device to the heat conductive substrate.

Optionally, bonding a heat generating region of a light emitting device to a heat conductive substrate comprises bonding a plurality of light emitting devices to a single heat conductive substrate.

Optionally, bonding a heat generating region of a light emitting device to a heat conductive substrate comprises bonding a plurality of light emitting devices of a single color to a single heat conductive substrate.

Optionally, bonding a heat generating region of a light emitting device to a heat conductive substrate comprises bonding a plurality of light emitting devices of a plurality of different colors to a single heat conductive substrate.

Preferably, bonding a heat generating region of a light emitting device to a heat conductive substrate comprises bonding a heat generating region of a light emitting device to a heat conductive substrate using a wafer bonding fixture.

Preferably, the light emitting device comprises a transparent substrate and the transparent substrate comprises at least one of Sapphire, ZnO, Spinel, MgO, GaN, AlN, AlGaN, and AlInGaN. Those skilled in the art will appreciate that various other materials are likewise suitable.

Preferably, the light emitting device comprises an n type semiconductor material and a p type semiconductor material disposed proximate the n type semiconductor material so as to define an active layer.

Preferably, the light emitting device comprises n type gallium nitride and p type gallium nitride disposed proximate the n type gallium nitride so as to define an active layer. Those skilled in the art will appreciate that various other materials are likewise suitable.

Preferably, the light emitting device comprises n type gallium nitride, p type gallium nitride disposed proximate the n type gallium nitride so as to define an active layer. The active layer preferably comprises either a double heterostructure, a single quantum well structure, or a multiple quantum well structure. Those skilled in the art will appreciate that various other structures are likewise suitable.

Preferably, a reflector is placed between the top semiconductor layer of the light emitting device and the bonding substrate. The reflector comprises a metal layer comprising at least one element from the group of Al, Ag, Au, Cr. Those skilled in the art will appreciate that various other materials are likewise suitable.

Preferably the reflector has a reflectivity at least 65% at the wavelength of light emitted from the active layer.

Preferably the reflector makes contact with the top semiconductor layer of the light emitting device on the opposite side of the light emitting device to the transparent substrate.

Preferably the contact between the reflector and the top semiconductor layer is ohmic or nearly ohmic.

Preferably, the light emitting device comprises a metal bonding layer which comprises a metal such as Pt, Ni, Au, or Ti. Those skilled in the art will appreciate that various other materials are likewise suitable.

Preferably, the heat conductive substrate comprises a material such as silicon, AlN, GaAs, InP, Ge, GaN, SiC, or ZnO. Alternatively, the heat conductive substrate comprises a metal. Those skilled in the art will appreciate that various other materials are likewise suitable.

Preferably the heat conductive substrate is also electrically conductive.

A p electrode and an n electrode electrically connected to the p layer and the n layer of the light emitting device respectively are preferably formed upon the composite device.

A passivation layer is preferably formed upon the composite device.

Positive and negative bonding pads are preferably formed upon the composite device.

Preferably the p and n electrodes of the LED are made on the same side of the composite device opposite to the transparent substrate.

These, as well as other advantages of the present invention, will be more apparent from the following description and drawings. It is understood that changes in the specific structure shown and described may be made within the scope of the claims, without departing from the spirit of the invention.

### BRIEF DESCRIPTION OF THE DRAWINGS

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

FIG. 1 is a schematic cross-sectional view showing layers of an exemplary light emitting device according to the present invention;

FIG. 2 is a schematic cross-sectional view showing layers of an exemplary submount according to the present invention;

FIG. 3 is a schematic cross-sectional view showing a composite device defined by the layers of the light emitting device of FIG. 1 after wafer bonding attachment thereof to the layers of the submount of FIG. 2;

FIG. 4 is a schematic cross-sectional view showing the composite device of FIG. 3 after further processing to add an n electrode, a passivation later, and bonding pads;

FIG. 5 is a schematic cross-sectional view showing the composite device of FIG. 3 showing both the n and p bonding pads.

FIG. 6 is a block diagram showing the process flow for forming the exemplary light emitting diode of FIGS. 1-5; and

FIG. 7 is a schematic top view showing the LED of FIG. 5.

### DETAILED DESCRIPTION OF THE PREFERRED EMBODIMENTS

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed herein even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims therefore include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

Thus, the detailed description set forth below in connection with the appended drawings is intended as a description of the presently preferred embodiments of the invention and is not intended to represent the only forms in which the present invention may be constructed or utilized. The description sets forth the functions and the sequence of steps for constructing and operating the invention in connection with the illustrated embodiments. It is to be understood, however, that the same or equivalent functions may be accomplished by different embodiments that are also intended to be encompassed within the spirit of the invention.

The present invention relates to a light emitting diode (LED) device and a method for producing and operating the same. More particularly, the present invention relates to an LED having an improved design and enhanced output characteristics. Even more particularly, the present invention relates to an AlInGaN LED assembly comprising a conductive substrate and a transparent top substrate. A method of manufacturing the device comprises the growth of the light emitting region on a permanent transparent substrate, wafer bonding of a conductive substrate of Silicon to the light emitting region, subsequent thinning of both the transparent and conductive substrate, followed by backside via metal contact formation and subsequent bonding of electrodes.

Preferably, the conductive substrate is both thermally and electrically conductive.

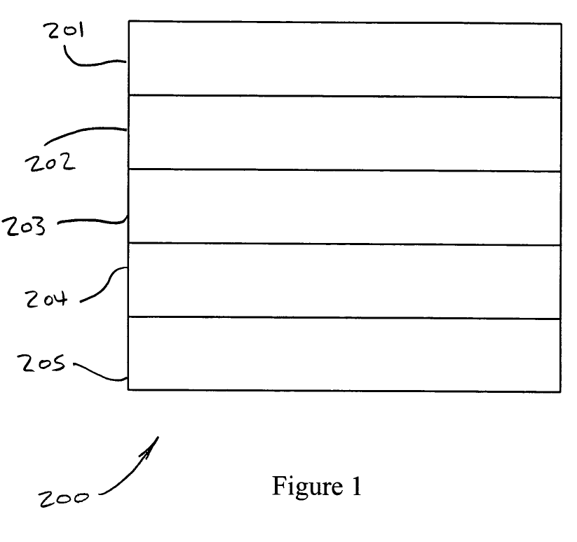

The present invention is illustrated in FIGS. 1-7, which depict a presently preferred embodiment thereof.

The present invention provides an LED chip which is configured so as to mitigate the above discussed problems associated with increased current and heat dissipation. The thermal conductivity of silicon is three times better than that of sapphire. Bonding the heat generating region of the device directly with a silicon substrate, for example, greatly enhances the heat dissipation from the LED. As those skilled in the art will appreciate, eliminating the heat from the heat source will improve the light output performance and reliability of the light emitting device.

Referring now to FIG. 1, a cross-sectional view of an exemplary light emitting device 200 includes a transparent substrate 201, a first layer 202, a second layer 203, a reflector layer 204, and a bonding metal layer 205. The light emitting device 200 comprises an active (light emitting) region of an LED. The first layer 202 and the second layer 203 are semiconductor layers which define the active region.

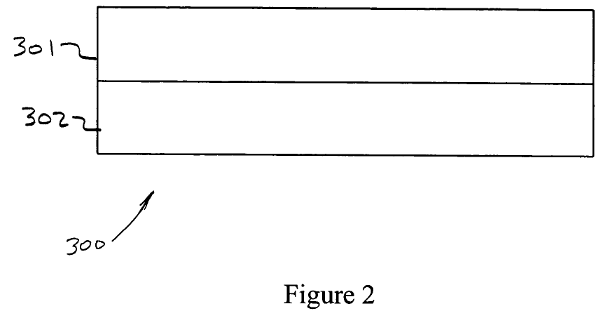

Referring now to FIG. 2, a cross-sectional view of an exemplary bonding substrate 300 (prior to wafer bonding attachment of the light emitting device 200 thereto) includes a thermally conductive substrate 301 and a bonding metal layer 302.

As discussed in detail below, the light emitting device of FIG. 1 is attached to the bonding substrate 300 of FIG. 2 to at least partially form the LED of the present invention.

Prior to the wafer bonding process, the surfaces of the metal bonding layers 205 (FIG. 1) and 302 (FIG. 2) on the light emitting device 200 and the bonding substrate 300, respectively, are thoroughly cleaned. The light emitting device 200 and the bonding substrate 300 are then loaded into a wafer bonding fixture to facilitate attachment to one another.

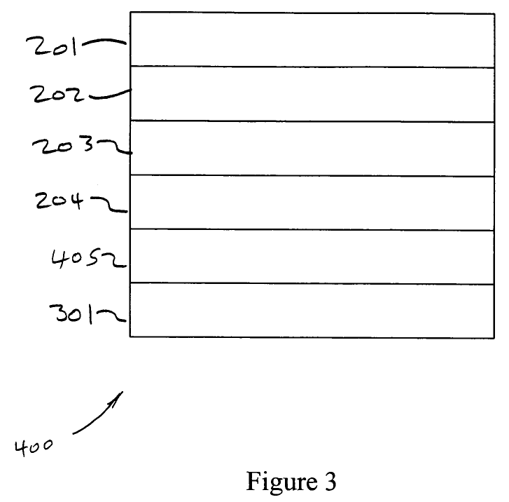

Referring now to FIG. 3, in the wafer bonding fixture the light emitting device 200 and the bonding substrate 300 are physically joined to form the composite light emitting device 400. Thus, the composite light emitting device 400 comprises both the light emitting diode structure 200 and the bonding substrate 300.

The composite device comprises a transparent substrate 201, a first layer 202, a second layer 203, a reflector layer 204, a metal joint layer 405, and a conductive substrate 301. The metal joint layer 405 is formed from the metal bonding layer 205 of the light emitting device 200 and the metal bonding layer 302 of the boning substrate device 300.

In operation, the active region defined by the first layer 202 and the second layer 203 emits light. One portion of the emitted light is transmitted directly from the device through the transparent substrate 201. Another portion of the emitted light is reflected from the reflective electrode 204, transmitted through the second layer 203 and the first layer 202, and is then transmitted out of the device through the transparent substrate 201.

The transparent substrate 201 can be sapphire, ZnO, Spinel, MgO, GaN, AlN, AlGaN, or AlInGaN. The material for forming the first layer 202 preferably includes an n type semiconductor material such as n type gallium nitride (n GaN). The material for forming the second layer 203 preferably includes a p type semiconductor material such as p type gallium nitride (p GaN).

An active light emitting layer 402 is formed between first layer 202 and second layer 203. Layer 402 can be a double heterostructure, single quantum well or multiple quantum well structure.

The reflector comprises a metal layer comprising at least one element from the group of Al, Ag, Au, Cr.

The metal joint layer 405 preferably includes multiple layers of metals. Materials for forming the metal joint layer 405 include chromium (Cr), platinum (Pt), nickel (Ni), gold (Au) and titanium (Ti).

The conductive substrate 406 can be silicon, Ge, GaAs, InP, GaP, SiC, ZnO, or any metal substrates.

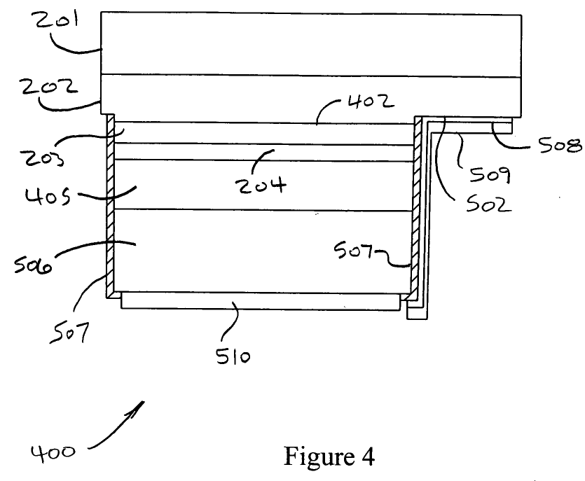

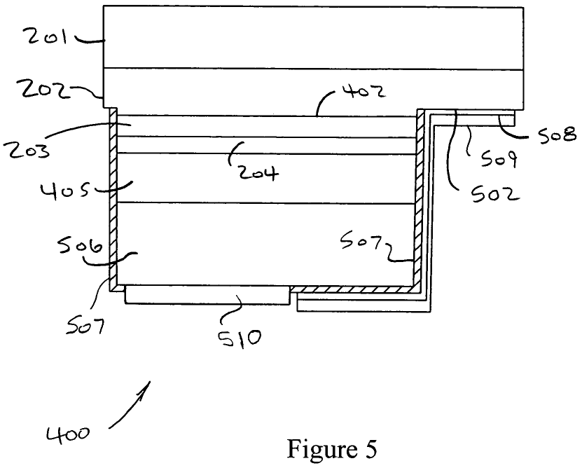

Referring now to FIGS. 4 and 5, the composite device 400 of FIG. 3 is further processed to include n electrode 508 passivation layer 507, as well as first and second bonding pads 509 and 510.

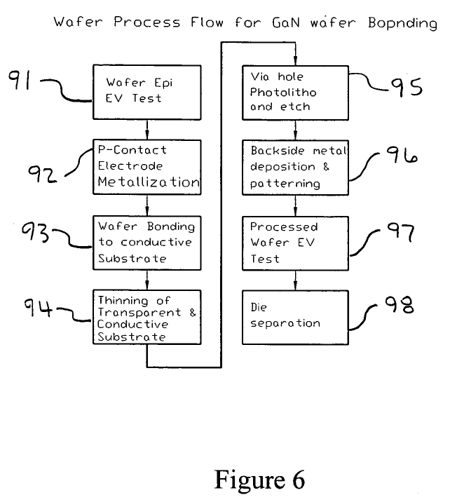

Referring now to FIG. 6, the process flow for forming an LED according to the present invention is shown. As shown in block 91, epitaxial growth and EV testing of the light emitting device 200 is performed according to well know principles.

As show in block 92, p contact electrode metalization is performed according to well know principles.

As shown in block 93, the light emitting device 200 is wafer bonded to a conductive substrate or submount 300.

As shown in block 94, thinning of the conductive substrate is performed. As those skilled in the art will appreciate, thinning may be performed by a variety of techniques, such as via chemical etching, mechanical material removal, or laser ablation.

As shown in block 95, at least one via hole is etched from the side of the conductive substrate 506. As those skilled in the art will appreciate, the via hole may be formed by a variety of techniques, such as chemical etching and laser drilling.

As shown in block 96, backside metal deposition and patterning is performed according to well know techniques.

As shown in block 97, processed wafer EV testing is performed according to well know principles.

As shown in block 98, die separation is performed so as to separate the wafer into a plurality of separate LED devices. Generally, a single LED device will be disposed upon each die. However, a plurality of LED devices may alternatively be formed upon each die as mentioned above. For example, as single die may optionally be formed so as to comprise a plurality of LEDs of a single color (so as to provide greater brightness).

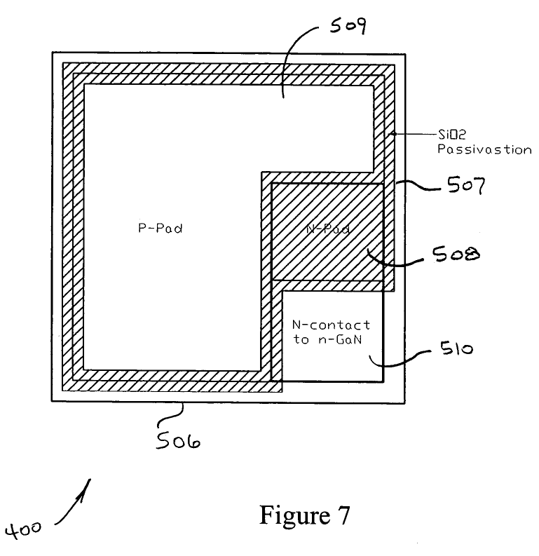

Referring now to FIG. 7, passivation layer 507 is optionally patterned and disposed on the side wall of the via opening and on portion of the top conductive substrate 506. The n electrode 508 is disposed on exposed n type gallium nitride 502a surface. The first bonding pad 509 and the second bonding pad 510 are then disposed on n electrode 508 and conductive substrate 506 respectively.

In view of the foregoing, the present invention provides an LED having a desirably high rate of direct heat removal from the LED active region, such as through the use of a higher thermal conductivity substrate on the backside thereof, which results in better LED reliability and higher current density operation; provides enhanced ESD performance; provides enhanced light output efficiency due to the inverted LED structure having a thicker transparent substrate on top of the emitting region without any metalization to block light emission and having an internal reflector to avoid absorption of the substrate material so as to allow more light escape from the chip due to a reduction of internal reflection.

Enhanced ESD protection is provided by the electrically conductive substrate.

It is understood that the exemplary light emitting diode described herein and shown in the drawings represents only a presently preferred embodiments of the invention. Indeed, various modifications and additions may be made to such embodiments without departing from the spirit and scope of the invention. For example, any desired number of light emitting devices may be attached to a single conductive substrate device.

Thus, these and other modifications and additions may be obvious to those skilled in the art and may be implemented to adapt the present invention for use in a variety of different applications.

1. A method for forming an LED, the method comprising bonding a heat generating region of a light emitting device to a heat conductive substrate so as to define a composite structure and so as to substantially enhance heat dissipation from the light emitting device.

2. The method as recited in claim 1, wherein bonding a heat generating region of a light emitting device to a heat conductive substrate comprises bonding a heat generating region of a light emitting device directly to a heat conductive substrate.

3. The method as recited in claim 1, wherein bonding the heat generating region of a light emitting device to a heat conductive substrate comprises bonding a heat generating region comprising the following to the heat conductive substrate:
an active layer;
an n-doped layer; and
a p-doped layer.

4. The method as recited in claim 1, wherein bonding the heat generating region of a light emitting device to a heat conductive substrate comprises bonding a heat generating region comprising the following to the heat conductive substrate:
an active layer;
an n-doped layer,
a p-doped layer; and
metal bonding layer.

5. The method as recited in claim 1, wherein bonding the heat generating region of a light emitting device to a heat conductive substrate comprises bonding a heat generating region comprising the following to the heat conductive substrate:
a transparent substrate;
an active layer;
an n-doped layer,
a p-doped layer; and
metal bonding layer.

6. The method as recited in claim 1, wherein bonding the heat generating region of a light emitting device to a heat conductive substrate comprises bonding a heat generating region comprising the following to the heat conductive substrate:
an active layer;
an n-doped layer;
a p-doped layer,
a reflector layer; and
metal bonding layer.

7. The method as recited in claim 1, wherein bonding the heat generating region of a light emitting device to a heat conductive substrate comprises bonding a heat generating region comprising the following to the heat conductive substrate:
a transparent substrate;
an active layer;
an n-doped layer;
a p-doped layer,
a reflector layer; and
metal bonding layer.

8. The method as recited in claim 1, wherein bonding the heat generating region of a light emitting device to a heat conductive substrate comprises bonding a heat generating region directly to a heat conductive substrate comprising:
a silicon layer; and
a metal bonding layer.

9. The method as recited in claim 1, wherein the heat generating region of the light emitting device comprises:
a transparent substrate;
an active layer;
an n-doped layer;
a p-doped layer,
a reflector layer;
metal bonding layer;
and the heat conductive substrate comprises:
a silicon layer; and
a metal bonding layer.

10. The method as recited in claim 1, wherein the heat generating region of the light emitting device comprises a metal bonding layer and the heat conductive substrate comprises a metal bonding layer and further comprising cleaning both metal bonding layers prior to bonding the heat generating region of a light emitting device to the heat conductive substrate.

11. The method as recited in claim 1, wherein bonding a heat generating region of a light emitting device to a heat conductive substrate comprises bonding a plurality of light emitting devices to a single heat conductive substrate.

12. The method as recited in claim 1, wherein bonding a heat generating region of a light emitting device to a heat conductive substrate comprises bonding a plurality of light emitting devices of a single color to a single heat conductive substrate.

13. The method as recited in claim 1, wherein bonding a heat generating region of a light emitting device to a heat conductive substrate comprises bonding a heat generating region of a light emitting device to a heat conductive substrate using a wafer bonding fixture.

14. The method as recited in claim 1, wherein the light emitting device comprises a transparent substrate and the transparent substrate comprises at least one material selected from the group consisting of:
ZnO;
Sapphire
Spinel;
MgO;
GaN;
AlN;
AlGaN; and
AlInGaN.

15. The method as recited in claim 1, wherein the light emitting device comprises:
an n type semiconductor material; and
a p type semiconductor material disposed proximate the n type semiconductor material so as to define an active layer.

16. The method as recited in claim 1, wherein the light emitting device comprises:
n type gallium nitride; and
p type gallium nitride disposed proximate the n type gallium nitride so as to define an active layer.

17. The method as recited in claim 1, wherein the light emitting device comprises n type gallium nitride, p type gallium nitride disposed proximate the n type gallium nitride so as to define an active layer, and wherein the active layer comprises at least one structure selected from the list consisting of:
a double heterostructure;
a single quantum well structure; and
a multiple quantum well structure.

18. The method as recited in claim 1, further comprising forming an n-electrode and a p-electrode on the same side of the composite structure.

19. The method as recited in claim 1, wherein the light emitting device comprises a reflector layer comprising a metal layer comprising one of the Al, Ag, Au, Cr.

20. The method as recited in claim 1, wherein the light emitting device comprises a metal bonding layer which comprises a metal selected from the group consisting of:
Ni;
Pt;
Au; and
Ti.

21. The method as recited in claim 1, wherein the heat conductive substrate comprises a material selected from the group consisting of:
silicon;
Ge;
SiC;
GaAs;
InP;
GaP
ZnO; and
a metal.

22. The method as recited in claim 1, further comprising forming an n electrode upon the composite device.

23. The method as recited in claim 1, further comprising forming a passivation layer upon the composite device.

24. The method as recited in claim 1, further comprising forming positive and negative bonding pads upon the composite device.

25. An LED comprising a light emitting device having a heat generating region and a heat conductive substrate to which the heat generating region is bonded, so as to define a composite structure and so as to substantially enhance heat dissipation from the light emitting device.

26. The LED as recited in claim 25 , wherein the heat generating region of the light emitting device is bonded directly to the heat conductive substrate.

27. The LED as recited in claim 25 , wherein the heat generating region comprises:
an active layer;
an n-doped layer; and
a p-doped layer.

28. The LED as recited in claim 25, wherein the heat generating region comprises:
an active layer;
an n-doped layer;
a p-doped layer; and
metal bonding layer.

29. The LED as recited in claim 25, wherein the heat generating region comprises:
a transparent substrate;
an active layer;
an n-doped layer,
a p-doped layer; and
metal bonding layer.

30. The LED as recited in claim 25 , wherein the heat generating region comprises:
an active layer;
an n-doped layer;
a p-doped layer,
a reflector layer; and
metal bonding layer.

31. The LED as recited in claim 25 , wherein the heat generating region comprises:
a transparent substrate;
an active layer;
an n-doped layer;
a p-doped layer;
a reflector layer; and
metal bonding layer.

32. The LED as recited in claim 25, wherein the heat conductive substrate comprises:
a silicon layer; and
a metal bonding layer.

33. The LED as recited in claim 25, wherein the heat generating region of the light emitting device comprises:
a transparent substrate;
an active layer;
an n-doped layer;
a p-doped layer;
a reflector layer;
metal bonding layer;
the heat conductive substrate comprises:
a silicon layer; and
a metal bonding layer.

34. The LED as recited in claim 25 , wherein the heat generating region of the light emitting device comprises a metal bonding layer and the heat conductive substrate comprises a metal bonding layer.

35. The LED as recited in claim 25 , wherein a plurality of light emitting devices are bonded to a single heat conductive substrate.

36. The LED as recited in claim 25 , wherein a plurality of light emitting devices of a single color devices are bonded to a single heat conductive substrate.

37. The LED as recited in claim 25 , wherein the light emitting device comprises a transparent substrate and the transparent substrate comprises at least one material selected from the group consisting of:
ZnO;
Sapphire;
Spinel;
MgO;
GaN;
AlN;
AlGaN; and
AlInGaN.

38. The LED as recited in claim 25 , wherein the light emitting device comprises:
an n type semiconductor material; and
a p type semiconductor material disposed proximate the n type semiconductor material so as to define an active layer.

39. The LED as recited in claim 25 , wherein the light emitting device comprises:
n type gallium nitride; and
p type gallium nitride disposed proximate the n type gallium nitride so as to define an active layer.

40. The LED as recited in claim 25 , wherein the light emitting device comprises n type gallium nitride, p type gallium nitride disposed proximate the n type gallium nitride so as to define an active layer, and wherein the active layer comprises at least one structure selected from the list consisting of:
a double heterostructure;
a single quantum well structure; and
a multiple quantum well structure.

41. The LED as recited in claim 25, further comprising an electrode formed upon the composite structure.

42. The LED as recited in claim 25 , further comprising an electrode of p type semiconductor material formed upon the composite structure.

43. The LED as recited in claim 25 , wherein the light emitting device comprises a reflector comprising a metal layer that comprises one of the Al, Ag, Au, Cr.

44. The LED as recited in claim 25 , wherein the light emitting device comprises a metal bonding layer which comprises a metal selected from the group consisting of:
Ni;
Pt;
Au; and
Ti.

45. The LED as recited in claim 25, wherein the heat conductive substrate comprises a material selected from the group consisting of:
silicon;
Ge;
SiC;
GaAs;
InP;
GaP;
ZnO; and
a metal.

46. The LED as recited in claim 25, further comprising an n electrode formed upon the composite device.

47. The LED as recited in claim 25 , further comprising a passivation layer formed upon the composite device.

48. The LED as recited in claim 25, further comprising positive and negative bonding pads formed upon the composite device.

49. An LED chip comprising a conductive substrate formed generally at one surface thereof, a transparent emitting substrate formed generally at another surface thereof and attached thereto by a direct wafer bonding technique, and backside via contacts.

50. The LED chip as recited in claim 49 , wherein the conductive substrate comprises at least one material selected from the group consisting of:
Si;
Ge;
SiC;
GaAs;
InP;
GaP;
ZnO; and
metal substrates.

51. The LED chip as recited in claim 49, wherein the transparent substrate comprises at least one material selected from the group consisting of:
sapphire;
spinel;
ZnO;
SiC;
MgO;
GaN;
AlN;
AlGaN; and
AlInGaN.

52. A reflective electrode comprising a single layer of reflective material formed upon p type gallium nitride layer, an n+ type gallium nitride interlayer form intermediate the reflective material and the p type gallium nitride layer, and at least one ohmic contact layer formed to the p type gallium nitride layer.

53. A reflective electrode comprising a plurality of layers of reflective material formed upon p type gallium nitride layer, an n+ type gallium nitride interlayer form intermediate the reflective material and the p type gallium nitride layer, and at least one ohmic contact layer formed to the p type gallium nitride layer.
